(19) United States
(12) Patent Application Publication
(10) Pub. No.: US 2006/0001098 A1
(43) Pub. Date: Jan. 5, 2006

(54) Electrostatic discharge protection device

(75) Inventors: Sheng-Chieh Yang, Taoyuan (TW); An Shih, Changhua (TW); Ming-Dou Ker, Hsinchu (TW); Tang-Kui Tseng, Hsinchu (TW)

Correspondence Address: MADSON & METCALF;GATEWAY TOWER WEST, SUITE 900, 15 WEST SOUTH TEMPLE, SALT LAKE CITY, UT, 84101, US

(73) Assignee: Toppoly Optoelectronics Corp.

(21) Appl. No.: 11/005,070

(22) Filed: Dec. 6, 2004

(30) Foreign Application Priority Data
Jul. 1, 2004 (TW) 093119914

(51) Int. Cl. H01L 23/62

(52) U.S. Cl. 257/355

(57) ABSTRACT

An electrostatic discharge (ESD) protection device for protecting an internal circuit includes a first ESD current unit and a second ESD current unit. The first ESD current unit is electrically connected between the internal circuit and a high source voltage for transmitting a discharging current to the high source voltage. The second ESD current unit is electrically connected between the internal circuit and a low source voltage for transmitting the discharging current to the low source voltage. Each of the first ESD current unit and the second ESD current unit has a first current path and a second current path interconnected in parallel for transmitting the discharging current to the high source voltage or the low source voltage. The first current path and the second current path pass through a MOS transistor and a diode, respectively.

### FIELD OF THE INVENTION

The present invention relates to an electrostatic discharge (ESD) protection device, and more particularly to an ESD protection device fabricated according to a low-temperature polysilicon technology.

### BACKGROUND OF THE INVENTION

TFTs (Thin Film Transistors) are widely used as basic elements for controlling pixels of a TFT liquid crystal display (TFT-LCD). In a TFT-LCD, the TFT units are typically formed on a glass substrate. Since the glass substrate is generally not refractory, the process for producing TFTs on the LCD glass plate should be a low-temperature manufacturing process. Such low-temperature polysilicon thin film transistor (LTPS-TFT) has improved electrical properties of TFT transistors. For example, the LTPS-TFT has larger electron mobility but lower threshold voltage when compared with the conventional TFT.

During the low-temperature manufacturing process, however, a great amount of electrostatic charges are generated and accumulated. In the event of electrostatic discharge, a current up to a few amps are generated within a short time interval. Such a discharging current has a destructive influence on the transistors in the internal circuit.

Referring to FIG. 1, a circuit diagram of a conventional ESD protection device is shown. The ESD protection device is employed to protect the internal circuit 10 from ESD damage by using two diodes to control conduction of the discharging current. The ESD protection device comprises a first diode 20, a second diode 30 and a resistor R. The P (positive) electrode and the N (negative) electrode of the first diode 20 are coupled to the internal circuit 10 and a high source voltage Vdd, respectively. Whereas, the P electrode and the N electrode of the second diode 30 are coupled to a low source voltage Vss and the internal circuit 10, respectively. The resistor R is connected between the internal circuit 10 and an input/output (I/O) pad 12 in series. In a case that electrostatic charges flow through the I/O pad 12, the discharging current will be transmitted to either the high source voltage Vdd or the low source voltage Vss via the first diode 20 or the second diode 30, respectively.

As shown in FIG. 1, the discharging current may be transmitted in one of the directions PD, NS, ND and PS. In such a manner, the internal circuit 10 can be protected from ESD damage. This ESD protection device has the inherent feature of the typical diode, e.g. a rapid response and a low tolerance. On the other hand, the tolerance of the forward-biased diode conduction (i.e. in the PD or NS mode) is larger than that of the reverse-biased diode conduction (i.e. in the ND or PS mode). Therefore, in the case that the discharging current is conducted in the reverse-biased ND or PS mode, the diodes are more readily damaged, when compared with a conventional metal oxide semiconductor. If positive charges, in respect to the low source voltage Vss, are inputted into the I/O pad 12, the discharging current will flow through the second diode 30 in the PS mode. Since the response and tolerance of this reverse-biased diode conduction are lower when compared with the forward-biased diode conduction, the discharging current may have a destructive influence on the internal circuit 10 and thus destroy the electronic components therein.

Referring to FIG. 2, a circuit diagram of another conventional ESD protection device is shown. This ESD protection device is employed to protect the internal circuit 40 from ESD damage by using two polysilicon MOS transistors to control conduction of the discharging current. The ESD protection device of FIG. 2 comprises a P-type polysilicon transistor 50, an N-type polysilicon transistor 60 and several resistors R1˜R5. The resistors R1 and R2 are connected between the internal circuit 40 and an I/O pad 42 in series. The gate electrode and the source electrode of the P-type polysilicon transistor 50 are coupled to one end of the resistor R3 and a high source voltage Vdd, respectively. The other end of the resistor R3 is coupled to the high source voltage Vdd. The drain electrode of the P-type polysilicon transistor 50 is coupled to a node “a” between the resistors R1 and R2. The gate electrode and the source electrode of the N-type polysilicon transistor 60 are coupled to one end of the resistor R4 and a low source voltage Vss, respectively. The other end of the resistor R4 is coupled to the low source voltage Vss. The drain electrode of the N-type polysilicon transistor 60 is also coupled to the node “a” between the resistors R1 and R2.

In a case that electrostatic charges flow through the I/O pad 42, the discharging current will be transmitted to either the high source voltage Vdd or the low source voltage Vss via the P-type polysilicon transistor 50 or the N-type polysilicon transistor 60, respectively.

The ESD protection device of FIG. 2 has the inherent feature of the typical MOS transistor, e.g. a slow response and a high tolerance. For example, the tolerance in the ND or PS mode is larger than that in the PD or NS mode. However, the response and the reliability in the ND or PS mode are inferior. Therefore, when the discharging current is conducted in the NS mode, the NMOS transistor is more readily damaged. Moreover, since the response of the MOS transistor is not rapid enough, when the electrostatic charges are inputted into the I/O pad 42, a portion of the discharging current may flow into and damage the internal circuit 40. The resistors R1, R2 and R5 may be suitable for reducing the impact of discharging current on the internal circuit 42 so as to offer sufficient time to turn on the PMOS transistor 50 and the NMOS transistor 60. However, the ESD protection benefit of this ESD protection device is not satisfactory. In addition, the arrangement of the resistors R1, R2 and R5 requires a larger layout area.

### SUMMARY OF THE INVENTION

The present invention provides an ESD protection device capable of rapidly conducting discharging current in either of the PS, ND, NS and PD mode so as to protect an internal circuit from ESD damage.

The present invention also provides a MOS layout area substantially identical to a typical MOS layer area for arranging thereon a MOS transistor and a diode interconnected in parallel.

In accordance with a first aspect of the present invention, there is provided an electrostatic discharge (ESD) protection device for protecting an internal circuit. The ESD protection device includes a first ESD current unit and a second ESD current unit. The first ESD current unit is electrically connected between the internal circuit and a high source voltage for transmitting a discharging current to the high source voltage. The second ESD current unit is electrically connected between the internal circuit and a low source voltage for transmitting the discharging current to the low source voltage. Each of the first ESD current unit and the second ESD current unit has a first current path and a second current path interconnected in parallel for transmitting the discharging current to the high source voltage or the low source voltage. The first current path and the second current path pass through a MOS transistor and a diode, respectively.

In one embodiment, the MOS transistor and the diode are integrated into a common integrated circuit.

In one embodiment, the integrated circuit is further defined with a first N-type region, a second N-type region, a P-type region and an intrinsic region. The P-type region is disposed in the first N-type region. The intrinsic region disposed between the first N-type region and the second N-type region. The first N-type region, the intrinsic region and the second N-type region are applied thereto conductive material to form a source electrode, a gate electrode and a drain electrode of the MOS transistor, respectively, and the P-type region, the intrinsic region and the second N-type region to form the diode.

In another embodiment, the integrated circuit is further defined with a first P-type region, a second P-type region, a N-type region and an intrinsic region. The N-type region is disposed in the first P-type region. The intrinsic region is disposed between the first P-type region and the second P-type region. The first P-type region, the intrinsic region and the second P-type region are applied thereto conductive material to form a source electrode, a gate electrode and a drain electrode of the MOS transistor, respectively. The N-type region, the intrinsic region and the second P-type region to form the diode.

The contents of the present invention will become more readily apparent to those ordinarily skilled in the art after reviewing the following detailed description and accompanying drawings, in which:

### BRIEF DESCRIPTION OF THE DRAWINGS

FIG. 1 is a circuit diagram illustrating a conventional ESD protection device by using two diodes to control conduction of the discharging current;

FIG. 2 is a circuit diagram illustrating another conventional ESD protection device by using two MOS transistors to control conduction of the discharging current;

FIG. 3(a) is a circuit diagram of an ESD protection device according to a preferred embodiment of the present invention;

FIG. 3(b) is a circuit diagram of an ESD protection device according to another preferred embodiment of the present invention;

FIGS. 4(a) and 4(b) are schematic cross-sectional views illustrating a structure of a parallel-connected NMOS transistor/diode pair;

FIG. 4(c) is a schematic cross-sectional view illustrating a structure of another parallel-connected NMOS transistor/diode pair; and

FIG. 4(d) is a schematic cross-sectional view illustrating a structure of a parallel-connected PMOS transistor/diode pair.

### DETAILED DESCRIPTION OF THE PREFERRED EMBODIMENT

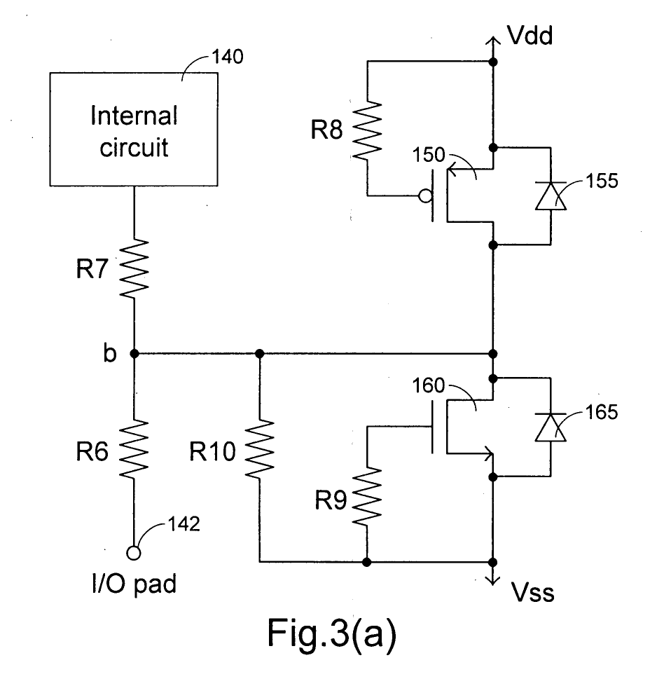

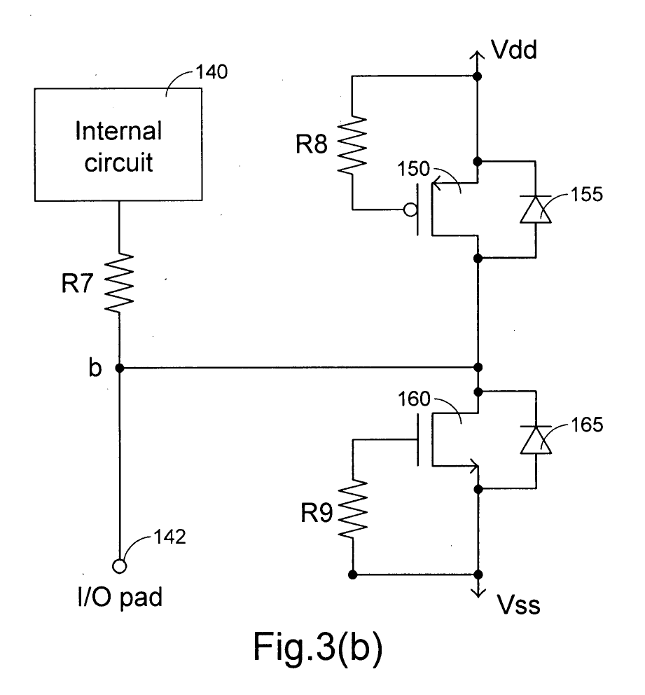

Referring to FIG. 3(a), a circuit diagram of an ESD protection device according to a preferred embodiment of the present invention is shown. This ESD protection device is employed to protect the internal circuit 140 from ESD damage by using two polysilicon MOS transistors and two diodes to control conduction of the discharging current. The ESD protection device of FIG. 3(a) comprises a P-type polysilicon transistor 150, an N-type polysilicon transistor 160, a first diode 155, a second diode 165 and several resistors R6˜R10. The resistors R6 and R7 are connected between the internal circuit 140 and an I/O pad 142 in series. Two end of the first diode 155 are interconnected in parallel to the source electrode and the drain electrode of the P-type polysilicon transistor 150, respectively. The gate electrode and the source electrode of the P-type polysilicon transistor 150 are also coupled to one end of the resistor R8 and a high source voltage Vdd, respectively. The other end of the resistor R8 is coupled to the high source voltage Vdd. The drain electrode of the P-type polysilicon transistor 50 is also coupled to a node “b” between the resistors R6 and R7. Two end of the second diode 165 are interconnected in parallel to the drain electrode and the source electrode of the N-type polysilicon transistor 160, respectively. The gate electrode and the source electrode of the N-type polysilicon transistor 160 are also coupled to one end of the resistor R9 and a low source voltage Vss, respectively. The other end of the resistor R9 is coupled to the low source voltage Vss. The drain electrode of the N-type polysilicon transistor 160 is also coupled to the node “b” between the resistors R6 and R7.

In a case that electrostatic charges flow through the I/O pad 142, the discharging current will be transmitted to either the high source voltage Vdd or the low source voltage Vss via the P-type polysilicon transistor 150 or the N-type polysilicon transistor 160, respectively.

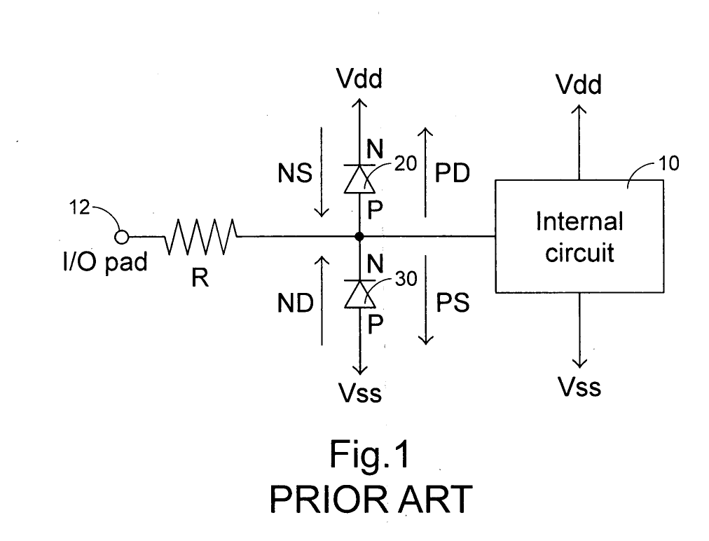

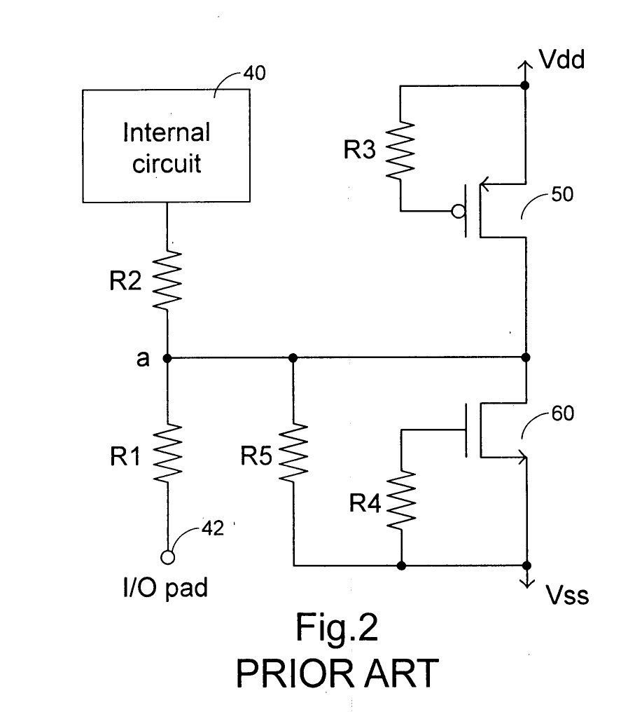

In the beginning when the discharging current is conducted in the NS mode, the MOS transistors 150 and 160 are not fully conducted, but the diode 155 or 165 is responsible for conduction of the discharging current due to the inherent rapid response thereof. As the discharging current increases, the MOS transistor 150 or 160 is then turned on, and offers an additional current path for transmitting the discharging current. Therefore, this ESD protection device can effectively protect the internal circuit 140 from ESD damage. In addition, the ESD protection device of this embodiment can offer a more rapid response than the device of FIG. 2, and a larger tolerance than the device of FIG. 1.

A further embodiment of an ESD protection device is illustrated in FIG. 3(b). In this embodiment, the resistors R6 and R10 in FIG. 3(a) are exempted so as to save the layout area.

Moreover, for a purpose of saving layout area of the ESD protection device, the structure of the parallel-connected MOS transistor/diode pair is specifically designed and then illustrated with reference to the following examples.

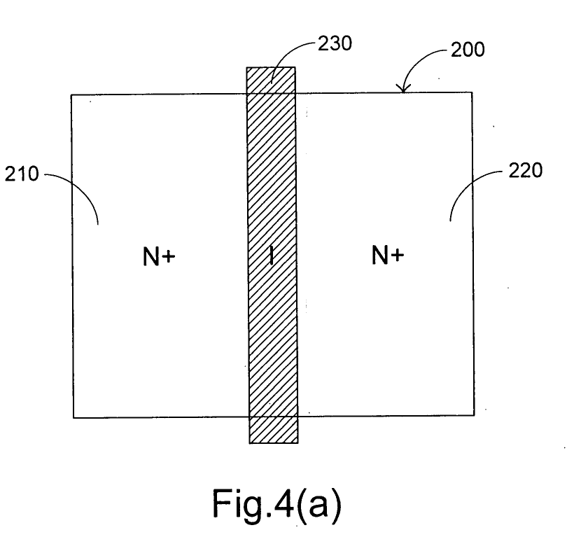

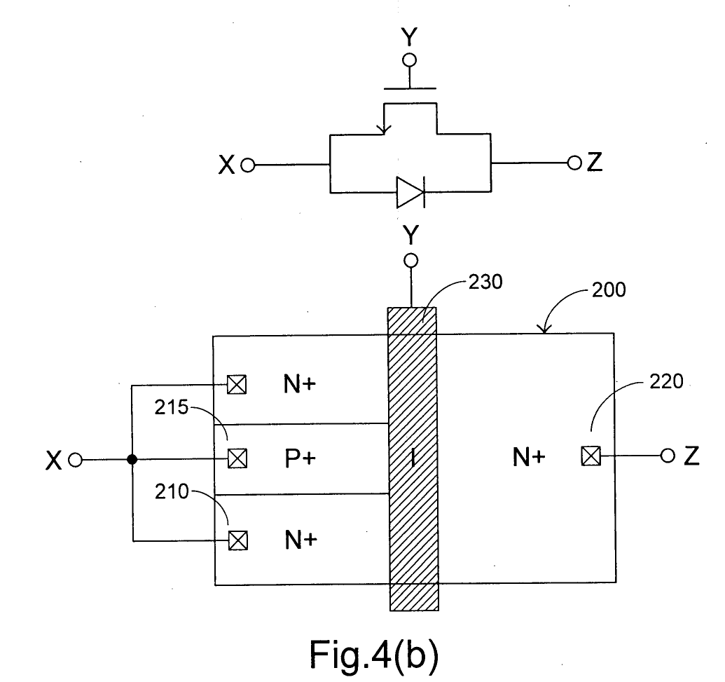

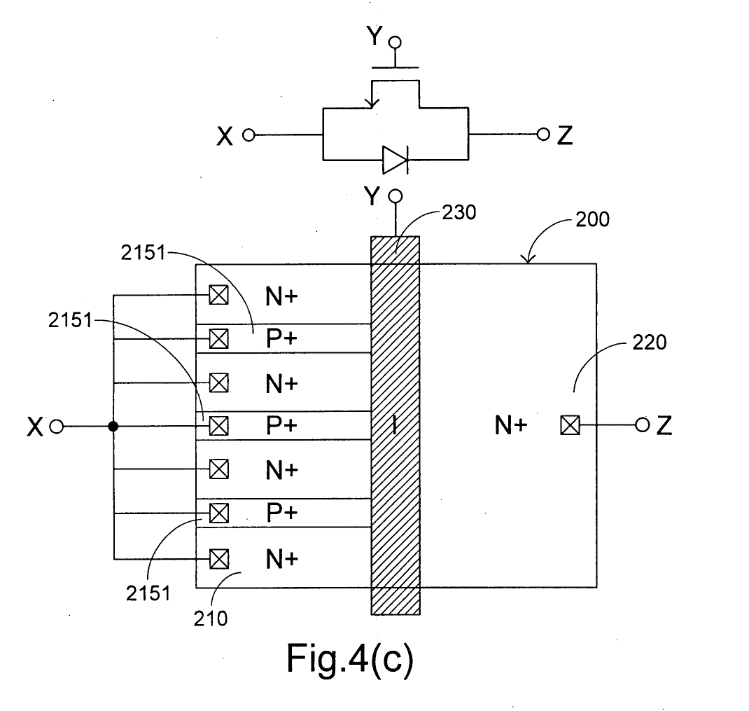

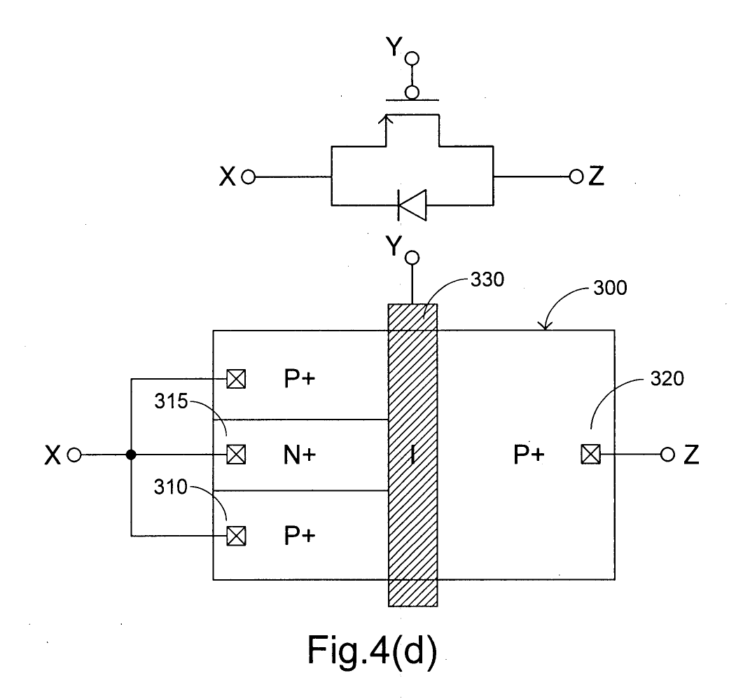

Referring to FIGS. 4(a) and 4(b), a structure of a parallel-connected NMOS transistor/diode pair is shown. As shown in FIG. 4(a), a layout area 200 substantial identical to that for fabricating a typical NMOS transistor is provided. The layout area 200 comprises two N-type regions 210 and 220 functioning as a source region and a drain region, respectively. In addition, a gate channel is formed in an intrinsic region 230 between these two N-type regions 210 and 220. By the way, the intrinsic region 230 can be of P-type, and a gate conductor (not shown) can be formed thereon. Subsequently, as shown in FIG. 4(b), a P-type region 215 is doped in the N-type region 210. The P-type region 215 can be dispose anywhere of the N-type region 210. For clarity, a P-type region 215 disposed in the center of the N-type region 210 is shown in the drawing. Then, some conductors or contacts are formed on the regions 210, 215 and 220. The P-type region 215 and the N-type regions 210 excluding the P-type region 215 are coupled to a common terminal X, the intrinsic region 230 is coupled to the terminal Y, and the N-type regions 220 is coupled to the terminal Z. Meanwhile, the P-type region 215, the intrinsic region 230 and the N-type regions 220 form a diode. In such a manner, two ends of the diode are interconnected in parallel to the source electrode and the drain electrode of the NMOS transistor, respectively.

Referring to FIG. 4(c), a structure of another parallel-connected NMOS transistor/diode pair is shown. The N-type regions 220 and the intrinsic region 230 included therein are similar to those shown in FIG. 4(b), and are not to be redundantly described herein. In this embodiment, several P-type regions 2151 are discretely arranged in the N-type region 210. The P-type regions 2151 and the N-type regions 210 excluding the P-type regions 2151 are coupled to a common terminal X, the intrinsic region 230 is coupled to the terminal Y, and the N-type regions 220 is coupled to the terminal Z. Meanwhile, the P-type regions 2151, the intrinsic region 230 and the N-type regions 220 form a diode. In such a manner, two ends of the diode are interconnected in parallel to the source electrode and the drain electrode of the NMOS transistor, respectively.

Referring to FIG. 4(d), a structure of a parallel-connected PMOS transistor/diode pair is shown. A layout area 300 substantial identical to that for fabricating a typical PMOS transistor is provided. The layout area 300 comprises two P-type regions 310 and 320 as a source region and a drain region, respectively. In addition, a gate channel is formed in an intrinsic region 330 between these two P-type regions 310 and 320. Subsequently, an N-type region 315 is doped in the P-type region 310. Likewise, the N-type region 315 can be dispose anywhere of the P-type region 310. For clarity, the N-type region 315 disposed in the center of the P-type region 310 is shown in the drawing. Then, some conductors or contacts are formed on the regions 310, 315 and 320. The N-type region 315 and the N-type regions 310 excluding the N-type region 315 are coupled to a common terminal X, the intrinsic region 330 is coupled to the terminal Y, and the P-type regions 320 is coupled to the terminal Z. Meanwhile, the N-type region 315, the intrinsic region 330 and the P-type regions 320 construct a diode. In such a manner, two ends of the diode are interconnected in parallel to the source electrode and the drain electrode of the PMOS transistor, respectively.

As will be understood from the above description, the ESD protection devices of the above embodiments are fabricated by using a low-temperature polysilicon complementary metal-oxide Semiconductor (LTPS CMOS) technology. A diode is parasitized in the layout area of a MOS transistor without using an additional photo mask, and thus the complexity and cost involving the fabricating process are minimized. The MOS transistor offers an additional current path for transmitting the discharging current so as to increases the response thereof. Furthermore, the tolerance of the ESD protection device according to the present invention is high and thus the pot life of related component is prolonged.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An electrostatic discharge (ESD) protection device for protecting an internal circuit, comprising:
a first ESD current unit electrically connected between said internal circuit and a high source voltage for transmitting a discharging current to said high source voltage; and
a second ESD current unit electrically connected between said internal circuit and a low source voltage for transmitting said discharging current to said low source voltage,
wherein each of said first ESD current unit and said second ESD current unit has a first current path and a second current path interconnected in parallel for transmitting said discharging current to said high source voltage or said low source voltage, and said first current path and said second current path pass through a MOS transistor and a diode, respectively.

2. The ESD protection device according to claim 1 wherein a source electrode and a drain electrode of said MOS transistor are coupled to said first current path.

3. The ESD protection device according to claim 2 wherein said MOS transistor is a low-temperature polysilicon MOS transistor.

4. The ESD protection device according to claim 1 wherein a gate electrode of said MOS transistor is coupled to the source electrode of said MOS transistor via a resistor.

5. The ESD protection device according to claim 1 wherein said MOS transistor and said diode are integrated into a common integrated circuit.

6. The ESD protection device according to claim 5 wherein said integrated circuit is further defined with:
a first N-type region;
a second N-type region;
a P-type region disposed in said first N-type region; and
an intrinsic region disposed between said first N-type region and said second N-type region,
wherein said first N-type region, said intrinsic region and said second N-type region are applied thereto conductive material to form a source electrode, a gate electrode and a drain electrode of said MOS transistor, respectively, and said P-type region, said intrinsic region and said second N-type region form said diode.

7. The ESD protection device according to claim 5 wherein said integrated circuit is further defined with:
a first P-type region;
a second P-type region;
an N-type region disposed in said first P-type region; and
an intrinsic region disposed between said first P-type region and said second P-type region,
wherein said first P-type region, said intrinsic region and said second P-type region are applied thereto conductive material to form a source electrode, a gate electrode and a drain electrode of said MOS transistor, respectively, and said N-type region, said intrinsic region and said second P-type region form said diode.

8. An electrostatic discharge (ESD) protection device for protecting an internal circuit, comprising:
a first MOS layout area for arranging thereon a first MOS transistor and a first diode interconnected in parallel, a source electrode and a drain electrode of said first MOS transistor being coupled to a first source voltage and said internal circuit, respectively, wherein the source electrode and the drain electrode of said first MOS transistor are further coupled to both terminals of said first diode, respectively; and
a second MOS layout area for arranging thereon a second MOS transistor and a second diode interconnected in parallel, a source electrode and a drain electrode of said second MOS transistor being coupled to a second source voltage and said internal circuit, respectively, wherein the source electrode and the drain electrode of said second MOS transistor are further coupled to both terminals of said second diode, respectively.

9. The ESD protection device according to claim 8 wherein said first MOS transistor is a PMOS transistor.

10. The ESD protection device according to claim 9 wherein said first source voltage is a high source voltage.

11. The ESD protection device according to claim 10 wherein said first MOS layout area comprises:
a first P-type region;
a second P-type region;
an N-type region disposed in said first P-type region; and
an intrinsic region disposed between said first P-type region and said second P-type region,
wherein said first P-type region, said intrinsic region and said second P-type region are applied thereto conductive material to form a source electrode, a gate electrode and a drain electrode of said PMOS transistor, respectively, and said N-type region, said intrinsic region and said second P-type region form said first diode.

12. The ESD protection device according to claim 8 wherein said second MOS transistor is a NMOS transistor.

13. The ESD protection device according to claim 12 wherein said second source voltage is a low source voltage.

14. The ESD protection device according to claim 13 wherein said second MOS layout area comprises:
a first N-type region;
a second N-type region;
a P-type region disposed in said first N-type region; and
an intrinsic region disposed between said first N-type region and said second N-type region,
wherein said first N-type region, said intrinsic region and said second N-type region are applied thereto conductive material to form a source electrode, a gate electrode and a drain electrode of said NMOS transistor, respectively, and said P-type region, said intrinsic region and said second N-type region form said second diode.

15. A MOS layout area for arranging thereon a PMOS transistor and a diode interconnected in parallel, said MOS layout area comprising:
a first P-type region;
a second P-type region;
an N-type region disposed in said first P-type region; and
an intrinsic region disposed between said first P-type region and said second P-type region,
wherein said first P-type region, said intrinsic region and said second P-type region are applied thereto conductive material to form a source electrode, a gate electrode and a drain electrode of said PMOS transistor, respectively, and said N-type region, said intrinsic region and said second P-type region to form said diode.

16. A MOS layout area for arranging thereon a NMOS transistor and a diode interconnected in parallel, said MOS layout area comprising:
a first N-type region;
a second N-type region;
a P-type region disposed in said first N-type region; and
an intrinsic region disposed between said first N-type region and said second N-type region,
wherein said first N-type region, said intrinsic region and said second N-type region are applied thereto conductive material to form a source electrode, a gate electrode and a drain electrode of said NMOS transistor, respectively, and said P-type region, said intrinsic region and said second N-type region to form said diode.
